(19) United States
(12) Patent Application Publication
(10) Pub. No.: US 2026/0182446 A1
(43) Pub. Date: Jun. 25, 2026

(54) ANGLED STIFFENER WITH DIRECTIVE FLOW ASSIST STRUCTURE FOR GLUE DISPENSE

(71) Applicant: Intel Corporation, Santa Clara, CA (US)

(72) Inventors: Min Suet LIM, Penang (MY); Seok Ling LIM, Penang (MY); Kavitha NAGARAJAN, Bangalore (IN); Eng Huat GOH, Penang (MY); Chun Keang OOI, Lunas (MY); Kyle DAVIDSON, Hillsboro, OR (US)

(21) Appl. No.: 19/001,256

(22) Filed: Dec. 24, 2024

(51) Int. Cl. H01L 23/04; H01L 23/06; H01L 23/26

(52) U.S. Cl. CPC H10W 76/12; H10W 76/17; H10W 76/48

(57) ABSTRACT

Embodiments disclosed herein may include an apparatus with a substrate, and a frame coupled to a surface of the substrate. In an embodiment, the frame includes a bottom surface that faces the substrate. a top surface, an inner surface that connects the bottom surface to the top surface, and an outer surface that connects the bottom surface to the top surface. In an embodiment, the outer surface is sloped with respect to the top surface.

### BACKGROUND

Large area package substrates require stiffeners in order to maintain the desired planarity for proper assembly and reliability. Components that are mounted adjacent to the stiffener may require underfill for reliability purposes as well. Accordingly, a keep out zone (KOZ) is necessary in order to allow a dispensing tool to be inserted between the component and an edge of the stiffener. The KOZ is otherwise unoccupied space and results in a lower area utilization of the package substrate. As such, the package substrate needs to be increased in area to accommodate the desired components. Larger packages are generally undesirable in many application spaces.

### BRIEF DESCRIPTION OF THE DRAWINGS

FIG. 1A is a plan view illustration of a package substrate with a stiffener and a plurality of components mounted to the stiffener, in accordance with an embodiment.

FIG. 1B is a cross-sectional illustration of a portion of a package substrate with a stiffener and an adjacent component that is being underfilled, in accordance with an embodiment.

FIG. 2A is a cross-sectional illustration of a portion of a package substrate with a stiffener that includes a sloped sidewall to decrease the size of a KOZ, in accordance with an embodiment.

FIG. 2B is a cross-sectional illustration of a portion of a package substrate with a stiffener that includes a sloped sidewall and a trench in the package substrate adjacent to the stiffener, in accordance with an embodiment.

FIG. 2C is a cross-sectional illustration of a portion of a package substrate with a stiffener that includes a coating over a sloped surface, in accordance with an embodiment.

FIG. 2D is a cross-sectional illustration of a portion of a package substrate with a stiffener that includes a coating over all surfaces, in accordance with an embodiment.

FIG. 2E is a cross-sectional illustration of a portion of a package substrate with a stiffener that includes a sloped inner surface and a sloped outer surface, in accordance with an embodiment.

FIG. 2F is a cross-sectional illustration of a portion of a package substrate with a stiffener with a sloped inner surface and a sloped outer surface where the inner surface and the outer surface have different slopes, in accordance with an embodiment.

FIG. 2G is a cross-sectional illustration of a portion of a package substrate with a stiffener with sloped inner and outer surfaces that are covered by a coating, in accordance with an embodiment.

FIG. 3A is a cross-sectional illustration of a portion of a package substrate with a stiffener with a sloped sidewall as an underfill is dispensed, in accordance with an embodiment.

FIG. 3B is a cross-sectional illustration of a portion of a package substrate with a stiffener with a sloped sidewall as an underfill is dispensed, in accordance with an embodiment.

FIG. 4 is a flow diagram of a process for applying an underfill to a component with a stiffener with a sloped sidewall adjacent to the component, in accordance with an embodiment.

FIG. 5 is a cross-sectional illustration of an electronic system with a stiffener with a sloped surface on a package substrate, in accordance with an embodiment.

FIG. 6 is a schematic of a computing device built in accordance with an embodiment.

### EMBODIMENTS OF THE PRESENT DISCLOSURE

Described herein are electronic systems with stiffeners with sloped sidewalls that allow for a decrease in the area of a keep out zone (KOZ) for underfill dispensing, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, many package substrates require a stiffener in order to meet planarity specifications. The stiffener occupies area on the package substrate. Additionally, components need to be spaced away from the stiffener by a distance (referred to as the keep out zone (KOZ)) in order to allow space for a dispensing tool to dispense underfill below the neighboring components. Typically, the KOZ has a width between 1.5 mm and 2.0 mm.

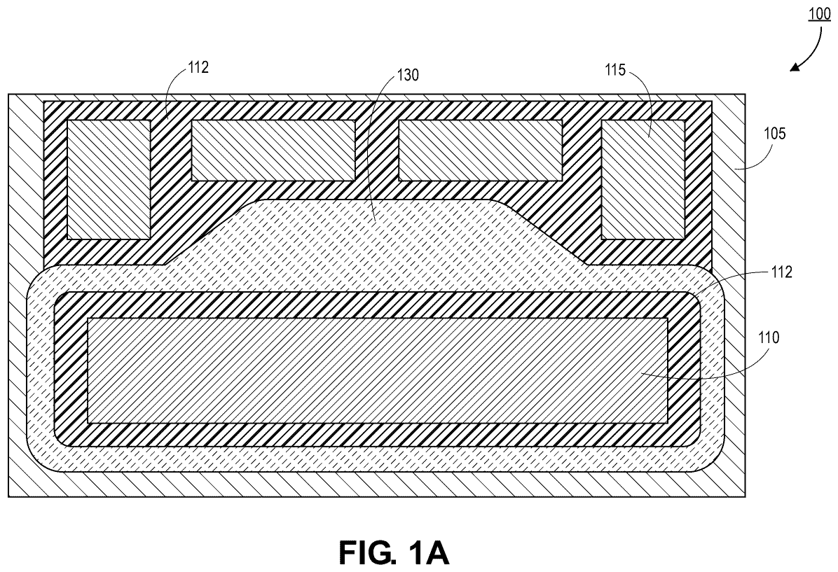

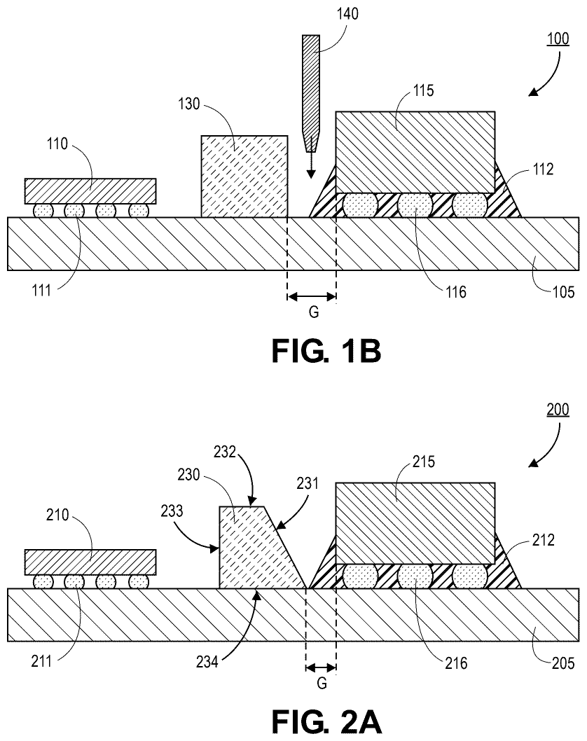

An example of an electronic system 100 is shown in FIG. 1A. As shown, a die 110 may be provided on a package substrate 105 and surrounded by a stiffener 130. An underfill 112 fills the space between the stiffener 130 and the die 110. Additional components 115 may be provided outside of the stiffener 130. For example, the die 110 may be a processor, and the additional components 115 may be memory dies or the like. The components 115 may be electrically coupled to the die 110 through routing (not shown) within the package substrate 105. Underfill 112 may also surround the components 115. As such, a KOZ is provided between edges of the components 115 and the outer edge of the stiffener 130.

FIG. 1B is a cross-sectional illustration of a portion of an electronic system 100 that shows the dispensing process of the underfill 112. As shown, the component 115 may be mounted to the package substrate 105 by solder interconnects 116 or the like. The underfill 112 is dispensed from a dispensing tool 140 (as indicated by the arrow). The dispensing tool 140 may be inserted between an edge of the stiffener 130 and an edge of the component 115. In order to accommodate the dispensing tool 140, a KOZ (indicated by the gap G) is provided between the stiffener 130 and the component 115. Typically, the gap G has a width of approximately 1.5 mm or more. While not shown, the die 110 may also have interconnects 111 that are surrounded by an underfill.

Typically, the KOZ is wasted space on the package substrate since no components can be placed in the KOZ. As such, it is desirable to minimize the width of the KOZ whenever possible. Accordingly, embodiments disclosed herein may include a stiffener that has a sloped sidewall. The sloped sidewall provides additional space for inserting the dispensing tool between the stiffener and the component. As such, the edge of the stiffener can be brought closer to the edge of the component, and the width of the KOZ is reduced. This may result in a stiffener with a first sidewall that is not parallel to a second sidewall. That is, the first sidewall may be along a first plane, and the second sidewall may be along a second plane that intersects the first plane. Stated differently, the stiffener may have a wedge-shaped profile in some embodiments.

In other embodiments, a coating may be applied to the stiffener. The coating may be a hydrophobic coating to help repel the underfill material away from the stiffener. As such, underfill that lands on the sloped sidewall of the stiffener during dispensing can flow down towards the component. This ensures that a consistent volume of underfill is applied to each component.

In yet another embodiment, a trench may be provided at an edge of the stiffener in the KOZ. The presence of the trench may prevent crack penetration from the stiffener to the package substrate. Crack penetration may otherwise occur due to the coefficient of thermal expansion (CTE) mismatch between the underfill and the package substrate solder resist materials.

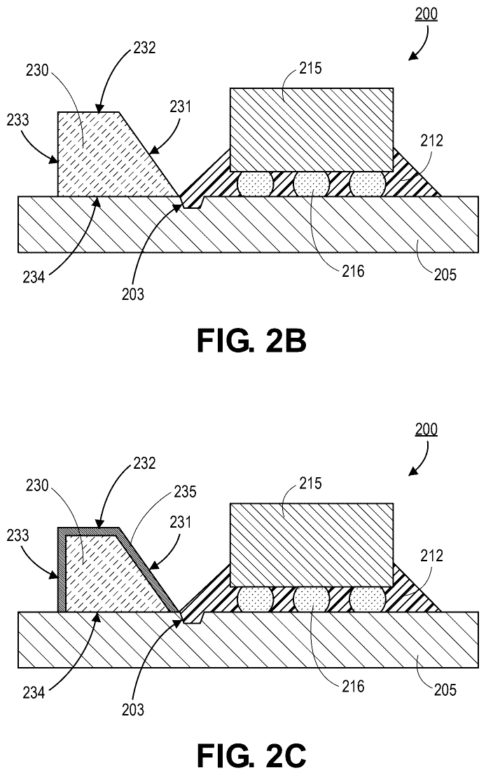

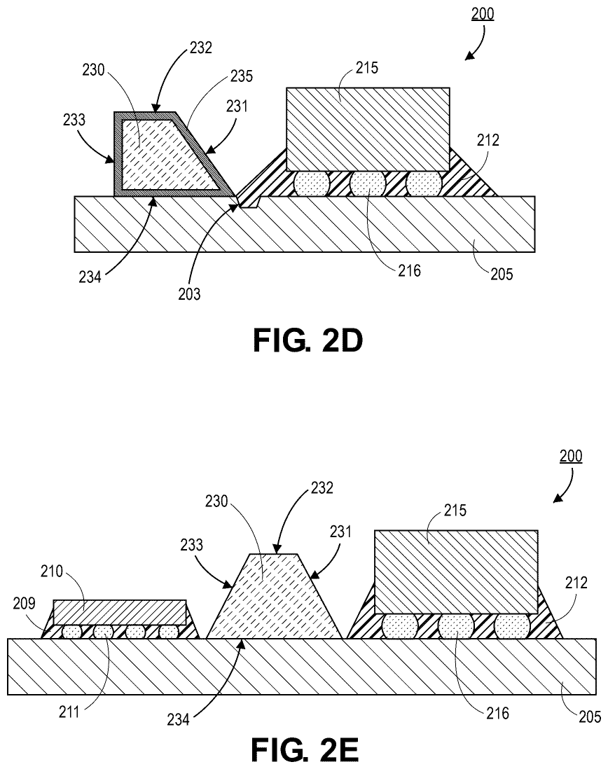

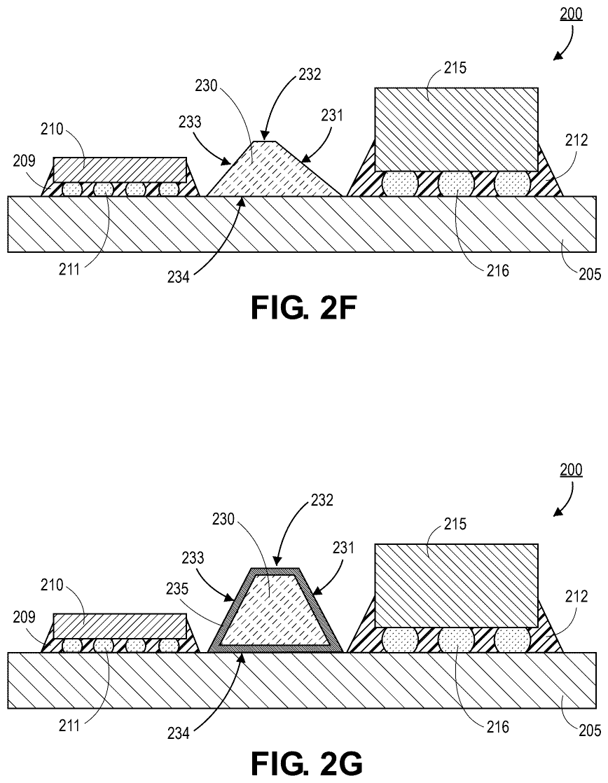

Referring now to FIG. 2A, a cross-sectional illustration of an electronic system 200 is shown, in accordance with an embodiment. In an embodiment, the electronic system may include a package substrate 205. The package substrate 205 may be an organic package substrate 205 with (or without) a core. In an embodiment, a die 210 may be electrically coupled to the package substrate 205 by interconnects 211. A component 215 may also be coupled to the package substrate 205 by interconnects 216. In an embodiment, electrical routing within the package substrate 205 may electrically couple the die 210 to the component 215. For example, the die 210 may be a processor, and the component 215 may be a memory die. Though, it is to be appreciated that other types of components 215 may be used, such as capacitors, inductors, communication modules, or any other type of die.

In an embodiment, a stiffener 230 may be provided between the die 210 and the component 215. For example, the stiffener 230 may surround a perimeter of the die 210, and the component 215 may be outside of the stiffener 230. For example, the stiffener 230 may have a shape similar to the stiffener 130 described in greater detail above with respect to FIG. 1A. The stiffener 230 may sometimes be referred to as a frame since the stiffener 230 has an inner surface and an outer surface. In an embodiment, the stiffener 230 may comprise a metallic material or any other high modulus material. For example, the stiffener 230 may comprise aluminum, stainless steel, or the like. While shown as being in direct contact with the package substrate 205, the stiffener 230 may be adhered to the package substrate 205 by an adhesive or the like.

In an embodiment, the stiffener 230 may comprise a first sidewall 231 and a second sidewall 233. The first sidewall 231 may be an outer sidewall that faces the component 215, and the second sidewall 233 may be an inner sidewall that faces the die 210. In an embodiment, the second sidewall 233 may be substantially vertical (e.g., orthogonal to a top surface 232 of the stiffener 230), and the first sidewall 231 may be sloped. That is, the first sidewall 231 may not be parallel to the second sidewall 233. The sloped first sidewall 231 allows for additional space to insert an underfill dispensing tool between the first sidewall 231 and the component 215 in order to dispense an underfill 212 around the interconnects 216. The underfill 212 may comprise any suitable underfill material that provides improved reliability to the electronic system 200. For example, the underfill 212 may comprise an epoxy or the like. In an embodiment, a slope of the first sidewall may be up to approximately 80°, up to approximately 60°, or up to approximately 45° (where the angle is measured between the first sidewall 231 and a bottom surface 234 of the stiffener 230).

In an embodiment, the sloped first sidewall 231 may allow for a reduction in the width of a KOZ between the stiffener 230 and the component 215. For example a gap G between an edge of the stiffener 230 and the component 215 may be approximately 1.5 mm or less, approximately 1.0 mm or less, or approximately 0.5 mm or less. As such, more space on the package substrate 205 can be used, and/or the area of the package substrate 205 may be reduced.

Referring now to FIG. 2B, a cross-sectional illustration of a portion of an electronic system 200 is shown, in accordance with an additional embodiment. In an embodiment, the electronic system 200 in FIG. 2B may be similar to the electronic system 200 in FIG. 2A, with the exception of the addition of a trench 203 in the package substrate 205. In an embodiment, the trench 203 may be used to improve the resistance to crack propagation. For example, CTE mismatch between the underfill 212 and the package substrate 205, solder resist materials can be mitigated by providing a reservoir for the underfill 212 into and/or through the solder resist layer.

In an embodiment, the trench 203 is formed at the edge of the stiffener 230. For example, an edge of the trench 203 may be directly aligned with an edge of the first sidewall 231. In an embodiment, the trench 203 is formed with a laser ablation process. As such, sidewalls of the trench 203 may be sloped in some embodiments. In the illustrated embodiment, the trench 203 is completely filled with the underfill 212. Though, in other embodiments the underfill 212 may partially fill the trench 203. In yet another embodiment, the trench 203 may be provided at any location between the stiffener 230 and the component 215. For example, the trench 203 may be spaced away from the edge of the stiffener 230 in some instances.

Referring now to FIG. 2C, a cross-sectional illustration of a portion of an electronic system 200 is shown, in accordance with an additional embodiment. The electronic system 200 in FIG. 2C is similar to the electronic system 200 in FIG. 2B, with the exception of the addition of a coating 235 over the stiffener 230. The coating 235 may be a hydrophobic coating or layer, such as a coating comprising silicon and oxygen (e.g., SiO₂), a polymer, or the like. The use of a hydrophobic coating allows for the underfill 212 to flow down the sloped first sidewall 231 in order to dispense around the interconnects 216 more easily. This ensures a uniform dispense volume for the underfill 212. In the illustrated embodiment, the coating 235 is provided over the first sidewall 231, the second sidewall 233, and the top surface 232. Keeping the bottom surface 234 free from the coating may be used to improve the adhesion between the substrate 205 and the stiffener 230.

Referring now to FIG. 2D, a cross-sectional illustration of a portion of an electronic system 200 is shown, in accordance with an additional embodiment. In an embodiment, the electronic system 200 in FIG. 2D may be substantially similar to the electronic system 200 in FIG. 2C with the exception to the coating 235 on the stiffener 230. In an embodiment, the coating 235 may surround an entire perimeter of the stiffener 230. That is, the coating 235 may be provided over the bottom surface 234, the top surface 232, the first sidewall 231, and the second sidewall 233.

Referring now to FIG. 2E, a cross-sectional illustration of a portion of an electronic system 200 is shown, in accordance with an additional embodiment. In an embodiment, the electronic system 200 in FIG. 2E may be similar to any of the electronic systems described in greater detail herein, with the exception of the shape of the stiffener 230. In the illustrated embodiment, the stiffener 230 may have a first sidewall 231 and a second sidewall 233 that are both sloped with respect to the bottom surface 234. In the illustrated embodiment, the slopes of the first sidewall 231 and the second sidewall 233 are mirror images of each other.

Providing a slope to the second sidewall 233 allows for a reduction in a KOZ that may be needed for providing underfill 209 around interconnects 211 between a die 210 and the package substrate 205. The reduction in the necessary size of the KOZ allows for an increase in the useable space on the package substrate 205 and/or allows for a decrease in the overall footprint of the package substrate 205.

Referring now to FIG. 2F, a cross-sectional illustration of a portion of an electronic system 200 is shown, in accordance with an embodiment. In an embodiment, the electronic system 200 in FIG. 2F may be substantially similar to the electronic system 200 in FIG. 2E, with the exception of the stiffener 230. For example, the stiffener 230 may have a first sidewall 231 that has a shallower slope than a slope of the second sidewall 233. The difference between the slopes of the first sidewall 231 and the second sidewall 233 may be used to accommodate different KOZs requirements. For example, the first sidewall 231 may have a slope that is shallower than a slope of the second sidewall 233 to provide a smaller KOZ between the stiffener 230 and the component 215 compared to the KOZ between the stiffener 230 and the die 210.

Referring now to FIG. 2G is a cross-sectional illustration of a portion of an electronic system 200 is shown, in accordance with an embodiment. The electronic system 200 in FIG. 2G may be similar to the electronic system 200 in FIG. 2E with the addition of a coating 235 over the stiffener 230. The coating 235 may be a hydrophobic coating that is used to repel the underfill 209 and/or underfill 212 away from the stiffener 230. In the illustrated embodiment, the coating 235 is provided over the bottom surface 234, the top surface 232, the first sidewall 231, and the second sidewall 233. Though, in other embodiments, the coating 235 may be omitted from one or more surfaces of the stiffener 230. For example, the bottom surface 234 may remain uncoated in order to improve adhesion between the stiffener 230 and the package substrate 205.

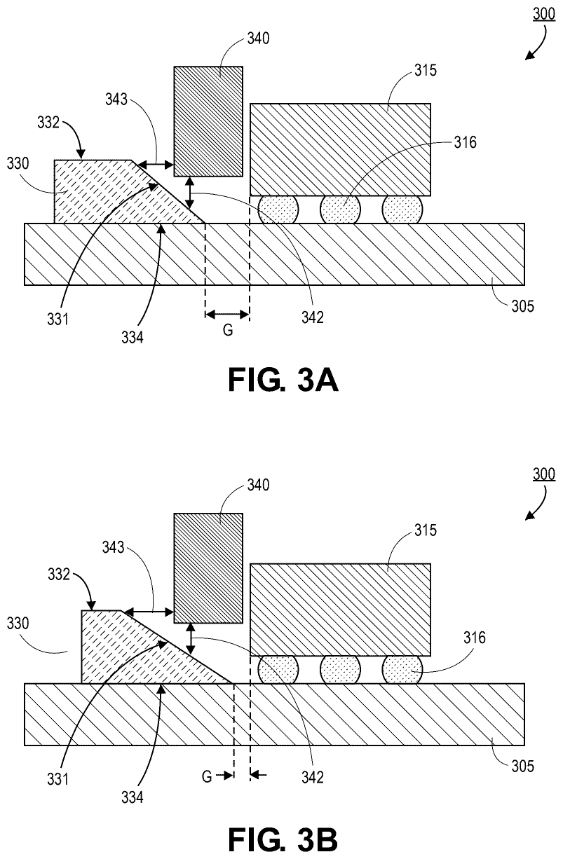

Referring now to FIGS. 3A and 3B, a pair of cross-sectional illustrations depicting electronic systems 300 with stiffeners 330 that have different slopes is shown, in accordance with an embodiment. In the embodiments shown in FIGS. 3A and 3B, the electronic systems 300 may be similar to any of those described in greater detail herein. For example, the electronic systems 300 may comprise a package substrate 305 with a component 315 electrically coupled to the package substrate 305 by interconnects 316. In an embodiment, a stiffener 330 is provided on the package substrate 305 adjacent to the component 315. The stiffener 330 may be similar to any of the stiffeners described in greater detail herein.

In an embodiment, the stiffener 330 may be coupled to the package substrate 305. For example, an adhesive (not shown) may be provided between a bottom surface 334 of the stiffener 330 and the package substrate 305. In an embodiment, the stiffener 330 may include a top surface 332 and a sloped first sidewall 331. The first sidewall 331 may be the outer sidewall of the stiffener 330, and the first sidewall 331 may face towards the component 315.

Altering the slope of the stiffener 330 allows for the width of the KOZ (i.e., the gap G) to be modified. For example, a shallower slope for the first sidewall 331 (e.g., FIG. 3B) allows for a smaller KOZ than a steeper slope (e.g., FIG. 3A). That is, the gap G can be decreased by making the slope of the first sidewall 331 shallower. The gap G can be decreased since the dispensing tool 340 can be moved further over the stiffener 330. That is, the underfill dispensing tool 340 can be inserted between the component 315 and the first sidewall 331 while still maintaining a desired clearance in the Z-direction 342 and the X-direction 343. For example, in FIG. 3A, the dispensing tool 340 is partially over the stiffener 330, whereas the dispensing tool 340 is nearly entirely over the stiffener 330 in FIG. 3B. Since the dispensing tool 340 is able to be moved towards the inner sidewall of the stiffener 330, the component 315 may also be move in towards the inner sidewall of the stiffener 330. Accordingly, the gap G is reduced.

While reducing the gap G may allow for space savings on the package substrate 305, reducing the slope of the first sidewall 331 reduces the volume of the stiffener 330. The reduction of the volume of the stiffener 330 may impact the stiffening capability of the stiffener 330. Though, in some embodiments, the volume may be modified by making the stiffener 330 taller to compensate for the loss in volume due to a sloped sidewall 331. In some embodiments, a balance between the desired stiffness and the desired space savings (in the X-Y plane) on the package substrate 305 and/or Z-height may be chosen in order to meet a desired design specification.

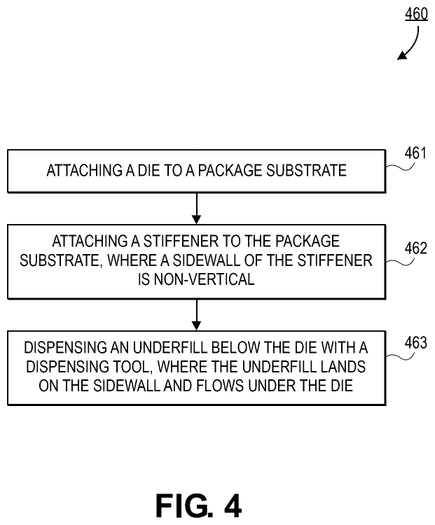

Referring now to FIG. 4, a flow diagram depicting a process 460 for underfilling a die or component on a package substrate is shown, in accordance with an embodiment. In an embodiment, the process 460 may include an underfilling process that allows for a reduced KOZ in order to increase useable space on a package substrate and/or to decrease a footprint of the package substrate.

In an embodiment, the process 460 may begin with operation 461, which comprises attaching a die or any other suitable component to a package substrate. In an embodiment, the die or component may be attached to the package substrate with any suitable interconnect. For example, the interconnects may include solder balls or the like. Some embodiments may refer to the interconnects as first level interconnects (FLIs).

In an embodiment, the process 460 may continue with operation 462, which comprises attaching a stiffener to the package substrate. The stiffener may be attached to the package substrate with any suitable mechanical coupling process, such as through the use of an adhesive or the like. In an embodiment a sidewall of the stiffener is non-vertical. That is, at least one sidewall of the stiffener may have a slope up to approximately 80°, up to approximately 60°, or up to approximately 45°. In an embodiment, the sloped sidewall of the stiffener may face towards the die or component. The stiffener may be similar to any of the stiffeners described in greater detail herein. In an embodiment, the stiffener may have a hydrophobic coating, and/or an additional sidewall surface may be sloped as well.

In the process 460 described herein, the die is mounted to the package substrate in operation 461, and the stiffener is mounted to the package substrate in operation 462. Though, it is to be appreciated that the stiffener may be mounted to the package substrate before the die is mounted to the package substrate in other embodiments. More generally, the order of the operations for process 460 are not listed in any specific order, and some or all of the operations may be practiced in any suitable order.

In an embodiment, the process 460 may continue with operation 463, which comprises dispensing an underfill below the die or component with a dispensing tool. In an embodiment, the underfill lands on the sidewall of the stiffener, and the underfill flows under the die or component. That is, the underfill may directly and intentionally contact the stiffener before flowing under the die or component. The slope of the stiffener allows for the underfill to naturally flow down towards the interconnects between the die (or component) and the package substrate. When a hydrophobic coating is provided on the stiffener, the flow of the underfill towards the die may be improved. In some embodiments, there may be no underfill remaining along the sloped sidewall surface of the stiffener after the dispensing process. In an embodiment, the underfill may include any suitable type of underfill, such as an epoxy or the like.

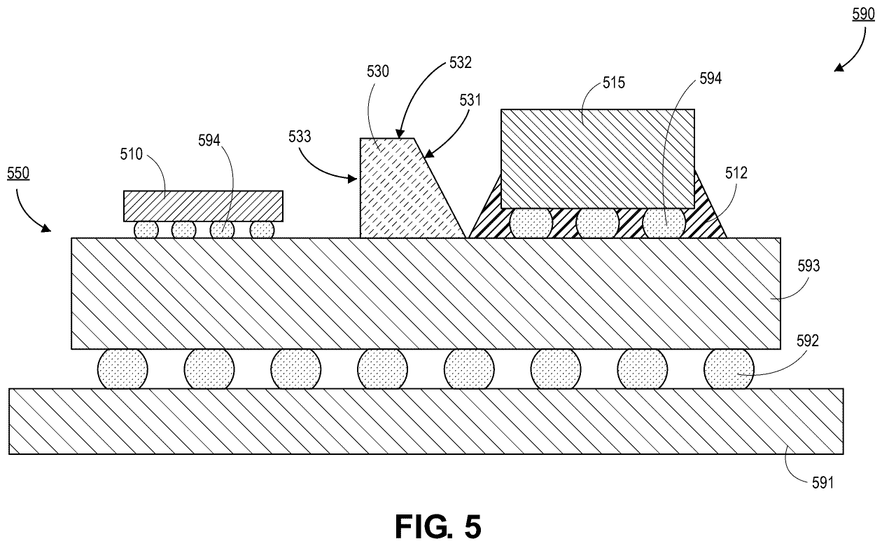

Referring now to FIG. 5, a cross-sectional illustration of an electronic system 590 is shown, in accordance with an embodiment. In an embodiment, the electronic system 590 may comprise a board 591, such as a printed circuit board (PCB), a motherboard, or the like. In an embodiment, the board 591 may be coupled to an electronic package 550 by second level interconnects (SLIs) 592. In an embodiment, the SLIs 592 may comprise solder balls, sockets, or the like.

In an embodiment, the electronic package 550 may comprise a package substrate 593. The package substrate 593 may be similar to any of the package substrates described in greater detail herein. For example, the package substrate 593 may comprise dielectric buildup layers over a core or the package substrate 593 may be coreless.

In an embodiment, a die 510 may be coupled to the package substrate 593 by FLIs 594, and a component 515 may be coupled to the package substrate 593 by FLIs 594. In an embodiment, the die 510 may be separated from the component 515 by a stiffener 530. The stiffener 530 may be configured to reduce a necessary KOZ between the stiffener 530 and the component 515. As such, the useable area of the package substrate 593 is increased and/or a footprint of the package substrate 593 may be decreased while maintaining at least the same functionality. In an embodiment, an underfill 512 may be provided around the FLIs 594.

In the illustrated embodiment, the stiffener 530 comprises a sloped first sidewall 531 and a substantially vertical second sidewall 533. A top surface 532 may connect the first sidewall 531 to the second sidewall 533. The stiffener 530 in FIG. 5 is uncoated. Though, a coating (e.g., a hydrophobic coating) may be provided over the first sidewall 531 and/or other surfaces of the stiffener 530. While a specific example of the stiffener 530 is illustrated in FIG. 5, it is to be appreciated that any of the stiffener architectures described in greater detail herein may be used in the electronic system 590.

In an embodiment, the underfill 512 may be dispensed under the component 515 (and/or around the FLIs 594) through the use of an underfill 512 dispensing process similar to process 460 described in greater detail herein. For example, after the component 515 and the stiffener 530 are mounted to the package substrate 593, a dispensing tool (not shown) may dispense the underfill 512 so that the underfill lands on the first sidewall 531 of the stiffener 530, flows down the first sidewall 531, and continuous along the package substrate 593 towards the FLIs 594 of the component 515.

In an embodiment, one or more dies 510 and/or components 515 may be coupled to the package substrate 593 by FLIs 594. The FLIs 594 may be any suitable FLI architecture, such as solder balls, copper bumps, or the like. In an embodiment, the one or more dies 510 may be any type of die (e.g., a processor die (e.g., a central processing unit (CPU), a graphics processing unit (GPU), an XPU), a memory die, a communications die, a power management die, and/or the like). In an embodiment, two or more dies 510 may be electrically coupled together by a bridge (not shown) that is embedded in the package substrate 593 or provided over the package substrate 593. In an embodiment, the components 515 may be any type of component, such as an inductor, a capacitor, a power delivery circuit, a power management circuit, a memory, a communications module, a processor, or the like.

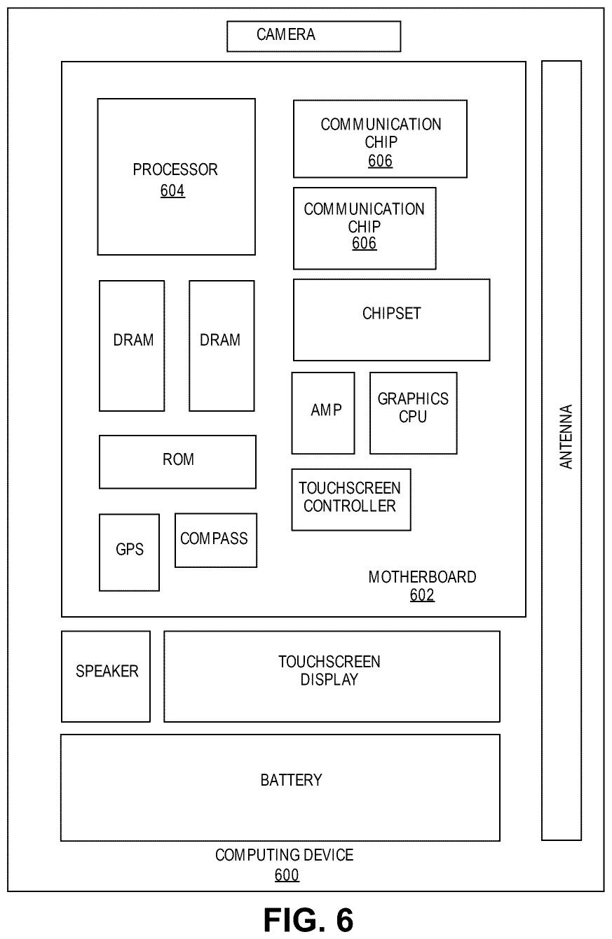

FIG. 6 illustrates a computing device 600 in accordance with one implementation of the disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604. In an embodiment, a device package is coupled to the board 602. One or both of the processor 604 or the communication chip 606 may be coupled to the board 602 through the device package.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the disclosure, the integrated circuit die of the processor may be part of a package substrate with a component that is adjacent to a stiffener that comprises a sidewall that is sloped to allow for a decrease in a width of a KOZ between the stiffener and the component, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the disclosure, the integrated circuit die of the communication chip may be part of a package substrate with a component that is adjacent to a stiffener that comprises a sidewall that is sloped to allow for a decrease in a width of a KOZ between the stiffener and the component, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### EXAMPLES

Example 1: an apparatus, comprising: a substrate; and a frame coupled to a surface of the substrate, wherein the frame comprises: a bottom surface that faces the substrate; a top surface; an inner surface that connects the bottom surface to the top surface; and an outer surface that connects the bottom surface to the top surface, wherein the outer surface is sloped with respect to the top surface.

Example 2: the apparatus of Example 1, wherein the outer surface and the inner surface are not parallel to each other.

Example 3: the apparatus of Example 2, wherein the inner surface is substantially vertical with respect to the top surface.

Example 4: the apparatus of Examples 1-3, wherein an angle between the bottom surface and the outer surface is up to approximately 80°.

Example 5: the apparatus of Examples 1-4, further comprising a layer over the outer surface.

Example 6: the apparatus of Example 5, wherein the layer comprises a hydrophobic material.

Example 7: the apparatus of Examples 1-6, further comprising: a die on the substrate outside of the frame; and an underfill between the die and the substrate.

Example 8: the apparatus of Example 7, further comprising: a trench between the outer surface of the frame and the die.

Example 9: the apparatus of Example 8, wherein the trench is at least partially filled by the underfill.

Example 10: the apparatus of Examples 1-9, wherein the frame comprises a metallic material.

Example 11: an apparatus, comprising: a substrate; a die on the substrate; a component on the substrate; and a frame that surrounds a perimeter of the die, wherein a portion of the frame is between the die and the component, and wherein the frame comprises: a first sidewall that faces the die, wherein the first sidewall is along a first plane; and a second sidewall that faces the component, wherein the second sidewall is along a second plane, and wherein the first plane intersects the second plane.

Example 12: the apparatus of Example 11, wherein the first plane is orthogonal to a top surface of the substrate.

Example 13: the apparatus of Example 11 or Example 12, wherein the second plane has an angle with respect to a bottom surface of the frame that is up to 80°.

Example 14: the apparatus of Examples 11-13, further comprising: a layer over the second sidewall of the frame.

Example 15: the apparatus of Example 14, wherein the layer comprises a hydrophobic material.

Example 16: the apparatus of Examples 11-15, further comprising: a trench between the frame and the component.

Example 17: the apparatus of Examples 11-16, wherein the frame comprises a metallic material.

Example 18: an apparatus, comprising: a package substrate; a die on the package substrate; a component on the package substrate; and a stiffener between the die and the component, wherein the stiffener comprises a first sidewall that faces the die and a second sidewall that faces the component, wherein the second sidewall is sloped with respect to a surface of the package substrate on which the die and the component are mounted.

Example 19: the apparatus of Example 18, further comprising: a hydrophobic layer over the second sidewall.

Example 20: the apparatus of Example 18 or Example 19, further comprising: a board coupled to the package substrate.

What is claimed is:

1. An apparatus, comprising:
a substrate; and
a frame coupled to a surface of the substrate, wherein the frame comprises:
a bottom surface that faces the substrate;
a top surface;
an inner surface that connects the bottom surface to the top surface; and
an outer surface that connects the bottom surface to the top surface, wherein the outer surface is sloped with respect to the top surface.

2. The apparatus of claim 1, wherein the outer surface and the inner surface are not parallel to each other.

3. The apparatus of claim 2, wherein the inner surface is substantially vertical with respect to the top surface.

4. The apparatus of claim 1, wherein an angle between the bottom surface and the outer surface is up to approximately 80°.

5. The apparatus of claim 1, further comprising a layer over the outer surface.

6. The apparatus of claim 5, wherein the layer comprises a hydrophobic material.

7. The apparatus of claim 1, further comprising:
a die on the substrate outside of the frame; and
an underfill between the die and the substrate.

8. The apparatus of claim 7, further comprising:
a trench between the outer surface of the frame and the die.

9. The apparatus of claim 8, wherein the trench is at least partially filled by the underfill.

10. The apparatus of claim 1, wherein the frame comprises a metallic material.

11. An apparatus, comprising:
a substrate;
a die on the substrate;
a component on the substrate; and
a frame that surrounds a perimeter of the die, wherein a portion of the frame is between the die and the component, and wherein the frame comprises:
a first sidewall that faces the die, wherein the first sidewall is along a first plane; and
a second sidewall that faces the component, wherein the second sidewall is along a second plane, and wherein the first plane intersects the second plane.

12. The apparatus of claim 11, wherein the first plane is orthogonal to a top surface of the substrate.

13. The apparatus of claim 11, wherein the second plane has an angle with respect to a bottom surface of the frame that is up to 80°.

14. The apparatus of claim 11, further comprising:
a layer over the second sidewall of the frame.

15. The apparatus of claim 14, wherein the layer comprises a hydrophobic material.

16. The apparatus of claim 11, further comprising:
a trench between the frame and the component.

17. The apparatus of claim 11, wherein the frame comprises a metallic material.

18. An apparatus, comprising:
a package substrate;
a die on the package substrate;
a component on the package substrate; and
a stiffener between the die and the component, wherein the stiffener comprises a first sidewall that faces the die and a second sidewall that faces the component, wherein the second sidewall is sloped with respect to a surface of the package substrate on which the die and the component are mounted.

19. The apparatus of claim 18, further comprising:
a hydrophobic layer over the second sidewall.

20. The apparatus of claim 18, further comprising:
a board coupled to the package substrate.
